(19) United States
(12) Patent Application Publication
(10) Pub. No.: US 2013/0242474 A1
(43) Pub. Date: Sep. 19, 2013

(54) ELECTRONIC DEVICE WITH INDICATOR LAMP

(71) Applicants: TING-TING ZHAO, Shenzhen City (CN); HE-LI WANG, Shenzhen City (CN)

(72) Inventors: TING-TING ZHAO, Shenzhen City (CN); HE-LI WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/598,650

(22) Filed: Aug. 30, 2012

(30) Foreign Application Priority Data
Mar. 14, 2012 (CN) 201210066660.0

(51) Int. Cl. H05K 7/00

(52) U.S. Cl. 361/679.01

(57) ABSTRACT

An electronic device includes a cover, a base, a circuit board, an indicator lamp mounted on the circuit board, and a light guide plate fixed to the cover. The cover includes a first sidewall with a first edge and a through hole adjacent to the first edge. The base includes a second sidewall with a second edge contacting the first edge, and a blocking tab with a top portion above the second edge. The base is coupled to the cover and cooperatively defines a receiving space accommodating the circuit board. The light guide member includes a first end surface facing the indicator lamp and a second end surface located within the through hole and facing an outside of the cover. The light guide plate is made of light pervious material. The blocking tab prevents light from leaking out through a gap formed between the first edge and the second edge.

### BACKGROUND

1. Technical Field

The present disclosure relates to an electronic device with an indicator lamp which can prevent light emitted by the indicator lamp from leaking through a gap formed between an upper housing and a lower housing.

2. Description of Related Art

Electronic devices, such as disc players and notebooks computers, always include several indicator lamps for indicating a state (e.g., power on state). A small gap may be formed between an upper housing and a lower housing of the electronic device because of an engagement tolerance. Light emitted by the indicator lamps may leak out through the small gap, which would adversely affect the appearance of the electronic device. Thus, a new type of electronic device which can prevent light from leaking through the gap between the upper housing and the lower housing is needed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a partial, isometric view of an electronic device in accordance with an exemplary embodiment.

FIG. 2 is a partial, isometric view of a cover of the electronic device shown in FIG. 1.

FIG. 3 is a partial, isometric view of a base of the electronic device shown in FIG. 1.

FIG. 4 is a cross-sectional view of the electronic device, cut along line IV-IV of FIG. 1.

### DETAILED DESCRIPTION

Embodiments of the present disclosure are described with reference to the accompanying drawings.

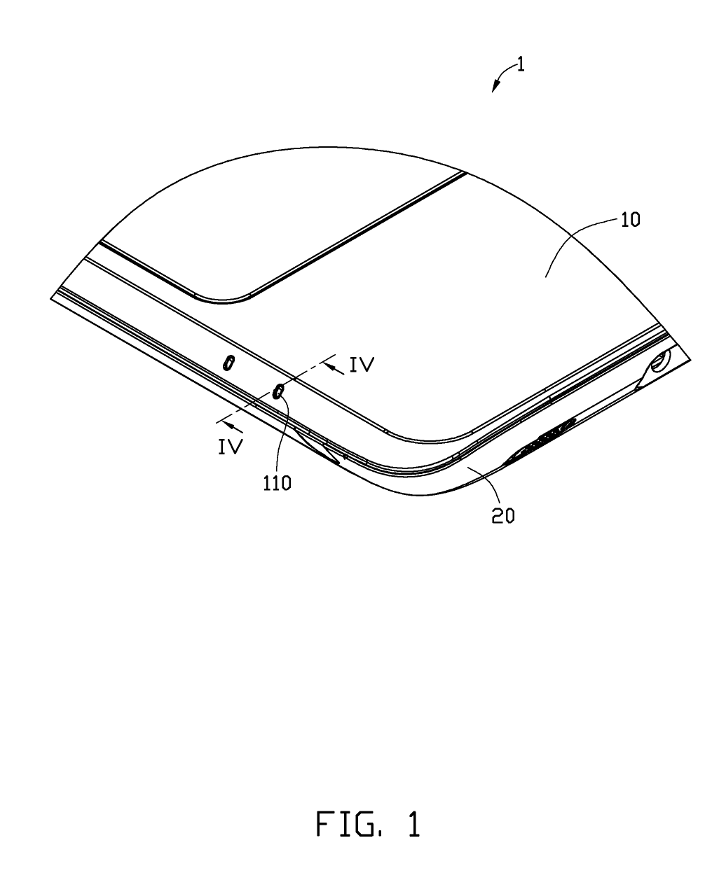

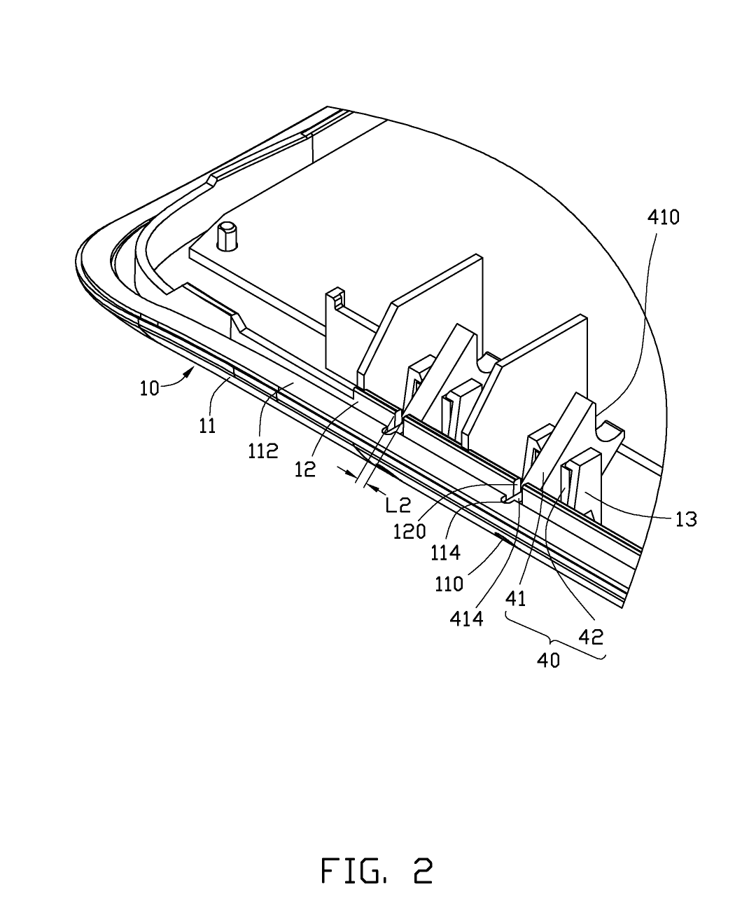

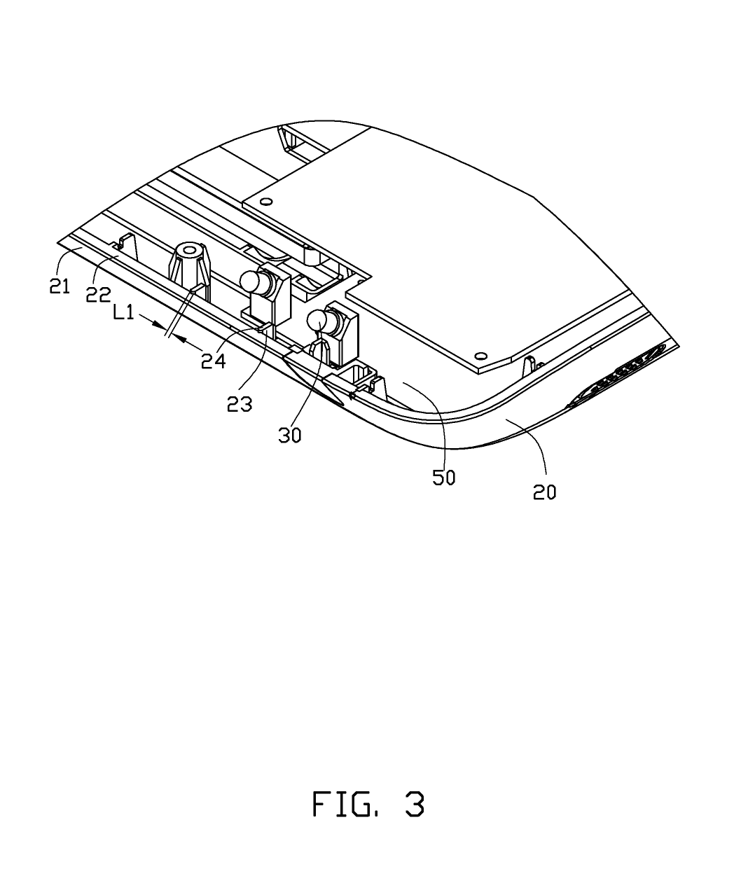

Referring to FIGS. 1-3, an electronic device 1 according to an exemplary embodiment is illustrated. The electronic device 1 includes a cover 10, a base 20, and a circuit board 50. The cover 10 and the base 20 cooperatively define a receiving space 60 therebetween, and the circuit board 50 is accommodated in the receiving space 60.

The cover 10 includes a top portion 14, a first sidewall 11 protruding from the top portion 14, a positioning plate 12, and two pairs of flexible hooks 13 protrude from an inner surface of the top portion 14. The first sidewall 11 defines two through holes 110 and includes a first edge 112 facing the base 20. The positioning plate 12 is substantially perpendicular to the first edge 112. The first edge 112 further defines a first notch 114, and the positioning plate 12 defines a second notch 120 substantially aligned with the first notch 114.

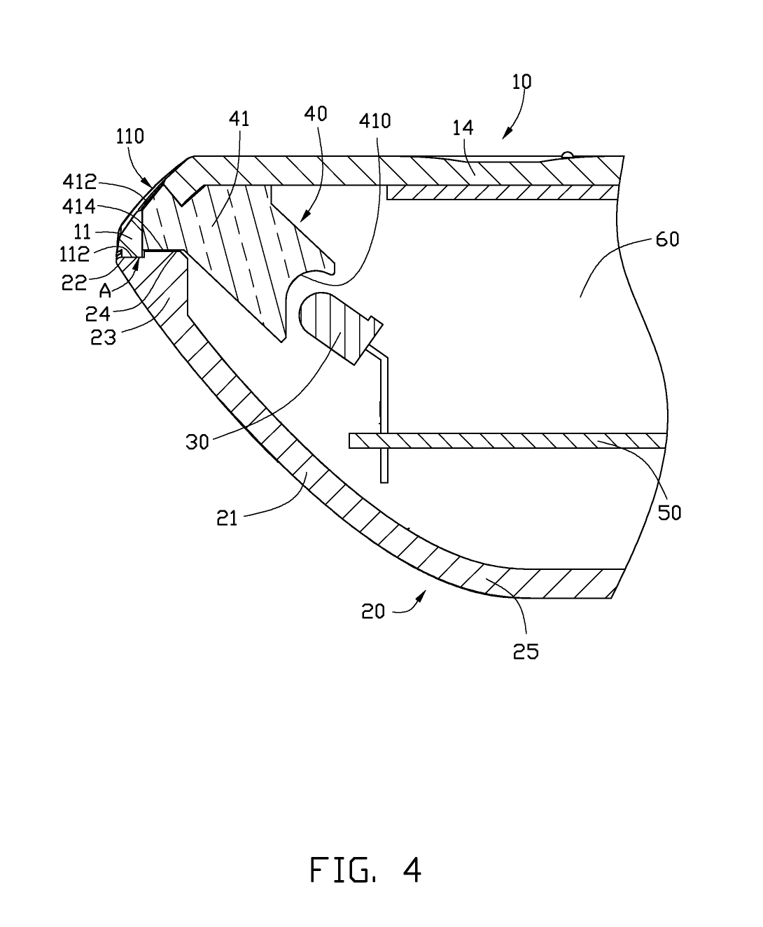

The base 20 includes a bottom portion 25, a the second sidewall 21 protruding from the bottom portion 25, and two blocking tabs 23 protruding from an inner side of the second sidewall 21. The second sidewall 21 includes a second edge 22 substantially parallel to the first edge 112. The blocking tab 23 includes a substantially horizontal top surface 24 raised relative to the second edge 22. A thickness L1 of the blocking tabs 23 is equal to a width L2 of the first notch 114 and the second notch 120. When the cover 10 is coupled to the base 20 and the first edge 112 contacts the second edge 22, a tiny gap A (shown in FIG. 4) is formed between the first edge 112 and the second edge 22 because of an engagement tolerance therebetween.

The indicator lamps 30 are mounted on the circuit board 50. In the embodiment, the indicator lamp 30 is a light emitting diode.

Referring also to FIG. 4, each light guide member 40 includes a main body 41 and two positioning blocks 42 protruding from opposite sides of the main body 41. The main body 41 is made of light pervious material. When attempting to couple the light guide member 40 to the cover 10, the two flexible hooks 13 are deflected away from each other, such that the light guide member 40 can be inserted into the first notch 114 and the second notch 120 of the base 20. The flexible hooks 13 are then released and engage the two positioning blocks 42, thereby holding the light guide member 40 in position. The main body 41 includes a first end surface 410 facing the indicator lamps 30, a second end surface 412 located within the first through hole 110 and facing an outside of the cover 10, and a third end surface 414 coming into tight contact with the top surface 24 of the base 20. In the embodiment, the first end surface 410 is a recessed arc-shaped surface. Light emitted from the indicator lamps 30 are refracted into the first end surface 410 and can be transmitted to the second side surface 410 and the third side surface 414.

The blocking tab 23 is inserted into the first notch 114 and the second notch 120 of the cover 10, and the top surface 24 is in tight contact with the third end surface 414 of the light guide member 40, thereby preventing light from leaking out through the gap A formed between the cover 10 and the base 20.

While various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. An electronic device comprising:
a cover comprising a first sidewall that comprises a first edge and defines a through hole adjacent to the first edge;
a base comprising a second sidewall with a second edge contacting the first edge, and a blocking tab comprising a top surface raised relative to the second edge, wherein the base and the cover are coupled to each other and cooperatively define a receiving space therebetween;
a circuit board accommodated in the receiving space;
an indicator lamp mounted on the circuit board;
a light guide member fixed to the cover, the light guide member each comprising a first end surface facing the indicator lamp, and a second end surface located within the through hole facing an outside of the cover, wherein the light guide plate is made of light pervious material;
wherein the blocking tab is configured to prevent light from leaking out through a gap formed between the first edge of the cover and the second edge of the base.

2. The electronic device as described in claim 1, wherein the first surface is a recessed arc-shaped surface.

3. The electronic device as described in claim 1, wherein the first edge defines a first notch, the cover comprises a positioning plate and a pair of flexible hooks, the positioning plate defines a second notch substantially aligned with the first notch, the light guide member comprises two positioning blocks at opposite sides thereof, and when the at least one guide plate is inserted into the first notch and the second notch, the flexible hooks engages the two positioning blocks, thereby fixing the light guide member to the cover.

4. The electronic device as described in claim 3, wherein a thickness of the blocking tab is substantially equal to a width of the first notch and the second notch.

5. The electronic device as described in claim 3, wherein the light guide member comprises a third end surface coming into tight contact with the top surface of the blocking tab.

6. The electronic device as described in claim 1, wherein the indicator lamp is a light emitted diode.
